(19) United States
(12) Patent Application Publication
(10) Pub. No.: US 2013/0234321 A1
(43) Pub. Date: Sep. 12, 2013

(54) SEMICONDUCTOR DEVICE AND METHOD FOR MANUFACTURING THE SAME

(71) Applicant: Woo Young CHUNG, Yongin-si (KR)

(72) Inventor: Woo Young CHUNG, Yongin-si (KR)

(73) Assignee: SK hynix Inc., Icheon-si (KR)

(21) Appl. No.: 13/609,053

(22) Filed: Sep. 10, 2012

(30) Foreign Application Priority Data
Mar. 12, 2012 (KR) 10-2012-0025051

(51) Int. Cl. H01L 21/283; H01L 21/768; H01L 23/498

(52) U.S. Cl. 257/737; 257/751; 438/586; 438/675; 257/E23.068; 257/E21.159; 257/E21.585

(57) ABSTRACT

The semiconductor device includes a plurality of pillar patterns formed over a semiconductor substrate. Each pillar pattern includes a silicon layer; a bit line junction region formed at the bottom of one side of the pillar pattern, and configured to be in contact the silicon layer; a bit line provided between the pillar patterns, coupled to the bit line junction region, and extending along a first direction; and a gate spaced apart from an upper part of the bit line, extending along a second direction perpendicular to the bit line, and formed at a sidewall of the pillar pattern.

### CROSS-REFERENCE TO RELATED APPLICATION

The present application claims priority to Korean patent application No. 10-2012-0025051 filed on 12 Mar. 2012, which is incorporated by reference in its entirety.

### BACKGROUND OF THE INVENTION

The present invention relates to a semiconductor device with a body tied pillar t and a method for forming the semiconductor device.

As the integration degree of a semiconductor device is increased, a channel length of a transistor is gradually decreased. However, the reduction in channel length of the transistor results in a Drain Induced Barrier Lowering (DIBL) phenomenon, a hot carrier effect, and a short channel effect such as punch-through. In order to solve such problems, a variety of methods are being intensively researched by many developers and companies. Such methods include, for example, a method for reducing a depth of a junction region, a method for relatively increasing a channel length by forming a recess in a channel region of a transistor, and the like.

However, as the integration density of a semiconductor memory device (especially, Dynamic Random Access Memory (DRAM)) approaches Gigabits, it is necessary to manufacture a smaller-sized transistor. Therefore, although the channel length is scaled down using a current planar transistor in which a gate electrode is formed over a semiconductor substrate and a junction region is formed at both sides of the gate electrode, it is still difficult to reduce a unit cell to a desired size. In order to solve the above-mentioned problems, a vertical channel transistor structure has been recently proposed.

A conventional vertical channel transistor has a double-gate and double-bit line structure. That is, each pillar is coupled to two gates and two bit lines. If two bit lines are formed at both sides of a pillar pattern, a pillar body becomes isolated from a semiconductor substrate, causing a floating body effect. If the floating body effect occurs, a retention time characteristic of a device deteriorates.

### BRIEF SUMMARY OF THE INVENTION

Various embodiments of the present invention are directed to providing a semiconductor device and a method for manufacturing the same that substantially obviate one or more problems due to limitations and disadvantages of the related art.

Embodiments of the present invention relate to a body tied structure for guaranteeing a space margin of a pillar pattern in which a bit line junction region is formed in a vertical gate structure so as to reduce the pillar floating body effect.

In accordance with an aspect of the present invention, a semiconductor device includes a plurality of pillar patterns formed over a semiconductor substrate, and each pillar pattern includes a silicon pattern; a bit line junction region formed at a bottom part of a first side of the pillar pattern, the bit line junction region being in contact with the silicon pattern; a bit line provided between the pillar patterns, coupled to the bit line junction region, and extending along a first direction; and a gate spaced apart from an upper part of the bit line, extending along a second direction perpendicular to the first direction, and formed at sidewalls of the pillar patterns.

The pillar pattern is formed by etching the semiconductor substrate.

Each pillar pattern includes one silicon pattern.

The silicon pattern extends deeper than the pillar pattern.

The bit line is includes any of titanium (Ti) film, titanium nitride (TiN) film, tungsten (W) film, and a combination thereof.

The gate is coupled to the plurality of pillar patterns.

The device further comprising a storage node junction region formed over the pillar pattern.

The device further comprising a storage node coupled to the storage node junction region, which is provided at an upper part of the pillar pattern.

In accordance with another aspect of the present invention, a method for manufacturing a semiconductor device includes forming a plurality of line patterns over a semiconductor substrate; forming a plurality of holes in the line pattern; forming a bit line junction region at a bottom part of a first sidewall of the line pattern; filling the hole to form a silicon layer; forming a bit line between two neighboring line patterns; forming an insulation film over the bit line; forming a plurality of pillar patterns by etching the line pattern and the insulation film; and forming a gate at a sidewall of the pillar patterns so that the gate extends in a direction that is perpendicular to a direction of the bit line.

The step of filling the hole to form the silicon layer may include forming a selective epitaxial growth (SEG) film by growing a silicon layer of the line pattern exposed by the hole.

The step of filling the hole to form the silicon layer may include depositing a silicon layer over the entire surface of the line pattern including the hole; and performing a planarization etching process until an upper part of the line pattern is exposed.

The formation of the bit line junction region further may include implanting ions into the first sidewall of the line pattern.

The implantation of ions may include a primary ion implantation process and a secondary ion implantation process, each of which is performed by a tilted ion implantation process, wherein the primary ion implantation process is performed from a different direction to the secondary ion implantation process.

The primary ion implantation process may be performed at an angle of 5°˜10° with respect to a surface of the semiconductor substrate.

The secondary ion implantation process may be performed at an angle of 10°˜15° with respect to a surface of the semiconductor substrate.

The formation of the selective epitaxial growth (SEG) film may be performed until the silicon layer fills up to an upper part of the hole.

The bit line may be formed of any one of a titanium (Ti) film, a titanium nitride (TiN) film, a tungsten (W) film, and a combination thereof.

Each of the pillar patterns may be formed to have one hole.

The formation of the gate further may include forming a gate conductive material at a bottom part between the pillar patterns; forming a spacer over the gate conductive material and at a sidewall of each pillar pattern; and etching the gate conductive material using the spacer as an etch mask.

The method further may comprise after the formation of the gate, forming a storage node junction region over the pillar patterns; and forming a storage node coupled to the storage node junction region over the pillar patterns.

In accordance with another aspect of the present invention, a semiconductor device may comprise an inner pillar extending upward from a substrate; an outer pillar surrounding the inner pillar; a bit line junction region formed in a first sidewall region of the outer pillar.

The outer pillar may include a second sidewall region coupled to the substrate, and the second sidewall region may be spaced apart from the first sidewall region by the inner pillar.

The outer pillar may include the substrate material.

The inner pillar may include a same material with the outer pillar or the substrate material.

The inner pillar may extend down to a first level, the bit line junction region may be formed at a second level, and the first level may be lower than the second level.

The inner pillar may extend down to a first level, the outer pillar may extend down to a third level, and the first level may be lower than the third level.

The bit line junction region may extend to an interface of the inner and the outer pillars, and the bit line junction region may not extend to the second sidewall region of the outer pillar.

The inner and the outer pillars are configured in a concentric pattern

In accordance with another aspect of the present invention, a method for manufacturing a semiconductor device may comprise forming a line pattern extending upward from a substrate and arranged along a first direction; patterning the line pattern to form an outer pillar having a hole inside; filling the hole to form an inner pillar pattern extending down to a first level; and forming a bit line junction region in a first sidewall region of the outer pillar.

The step of patterning the line pattern to form the outer pillar may comprise forming the hole inside the line pattern to extend down to the first level; and patterning the line pattern along a second direction perpendicular to the first direction to form the outer pillar pattern having the hole inside.

The inner and the outer pillars may be configured in a concentric pattern.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is perspective and cross-sectional views illustrating a semiconductor device according to an embodiment of the present invention.

FIGS. 2A to 2K are perspective and cross-sectional views illustrating a method for manufacturing a semiconductor device according to an embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. A semiconductor device and a method for manufacturing the same according to embodiments of the present invention will hereinafter be described with reference to the accompanying drawings.

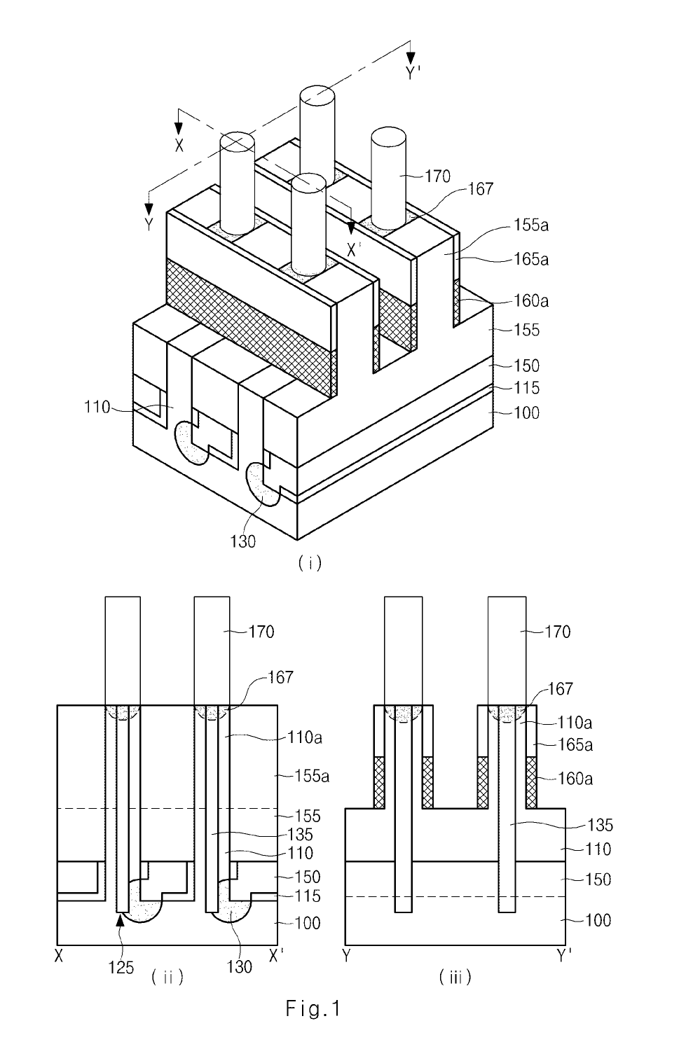

FIG. 1 is perspective and cross-sectional views illustrating a semiconductor device according to an embodiment of the present invention. FIG. 1(ii) is a cross-sectional view of a semiconductor device taken along the line X-X′ of FIG. 1(i). FIG. (iii) is a cross-sectional view of a semiconductor device taken along the line Y-Y′ of FIG. 1(i).

Referring to FIG. 1, the semiconductor device includes a bit line 150 buried between line patterns 110, and a gate 160a formed perpendicular to the bit line 150. Constituent elements of the semiconductor device will hereinafter be described in detail. A line pattern 110 is formed by etching the semiconductor substrate 100, and a plurality of silicon patterns 135 (also referred to as inner pillars) are contained in the line pattern 110. The silicon patterns 135 may vertically extend upward from the substrate 100. A bulb-shaped bit line junction region 130 is formed at the bottom of one side of the line pattern 110. The bit line junction region 130 is not limited only to a bulb shape, and can also be formed in any shape. The bit line junction region 130 may or may not be in contact with the silicon pattern 135. The bit line 150 coupled to the bit line junction region 130 is disposed between the line patterns 110. The bit line 150 may be formed of any one of a titanium (Ti) film, a titanium nitride (TiN) film, a tungsten (W) film, and a combination thereof. Preferably, the bit line 150 may be formed of a laminate structure of the titanium (Ti) film and the titanium nitride (TiN) film or a laminate structure of the titanium nitride (TiN) film and the tungsten (W) film. The bit line 150 and the bit line junction region 130 together form a bit line structure.

A gate 160a is formed over the bit line 150 in such a manner that the gate 160a extends in a direction that is perpendicular to the bit line 150. The gate 160a is formed at both sides of each pillar pattern 110a (also referred to as an outer pillar), which is formed by etching an upper part of the line pattern 110, and may be formed to interconnect a plurality of pillar patterns 110a. The outer pillar pattern 110a and the inner pillar pattern 135 may form a concentric pattern in a plan view. A storage node junction region 167 is formed over the pillar pattern 110a, and a storage node 170 coupled to the storage node junction region 167 is formed over the pillar pattern 110a.

As described above, the silicon pattern 135 is formed in the pillar pattern 110a and the line pattern 110, such that a predetermined distance between the bit line junction region 130, which is formed at the bottom of line pattern 110, and an adjacent line pattern 110 can be maintained by the silicon pattern 135. As a result, the pillar pattern 110a is tied to the substrate 100 through the line pattern 110 that is spaced apart from the junction region 130, thus preventing the floating body effect.

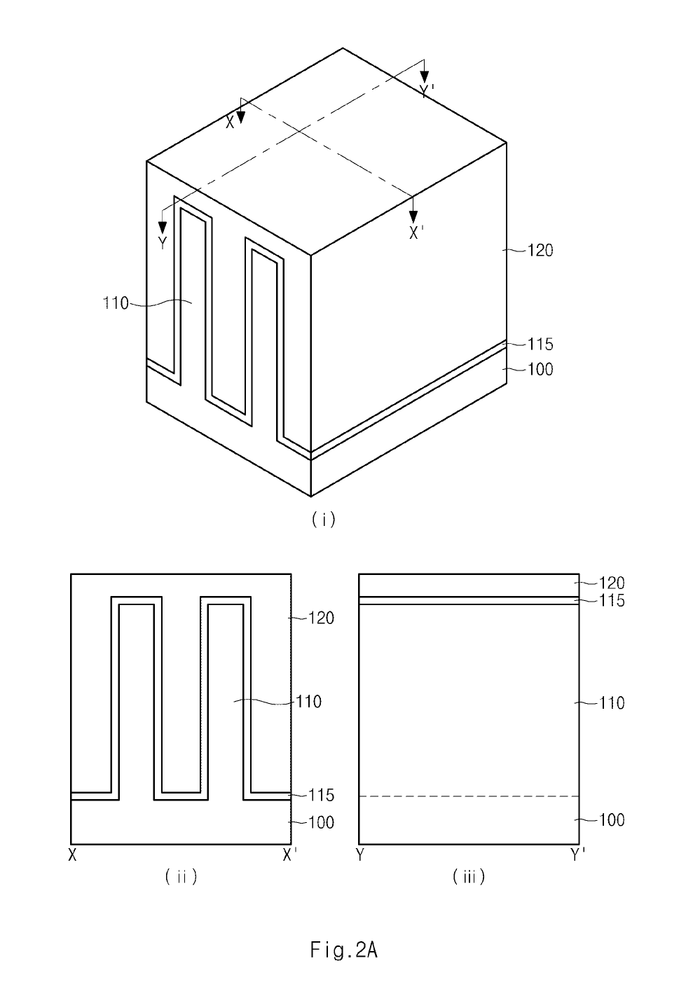

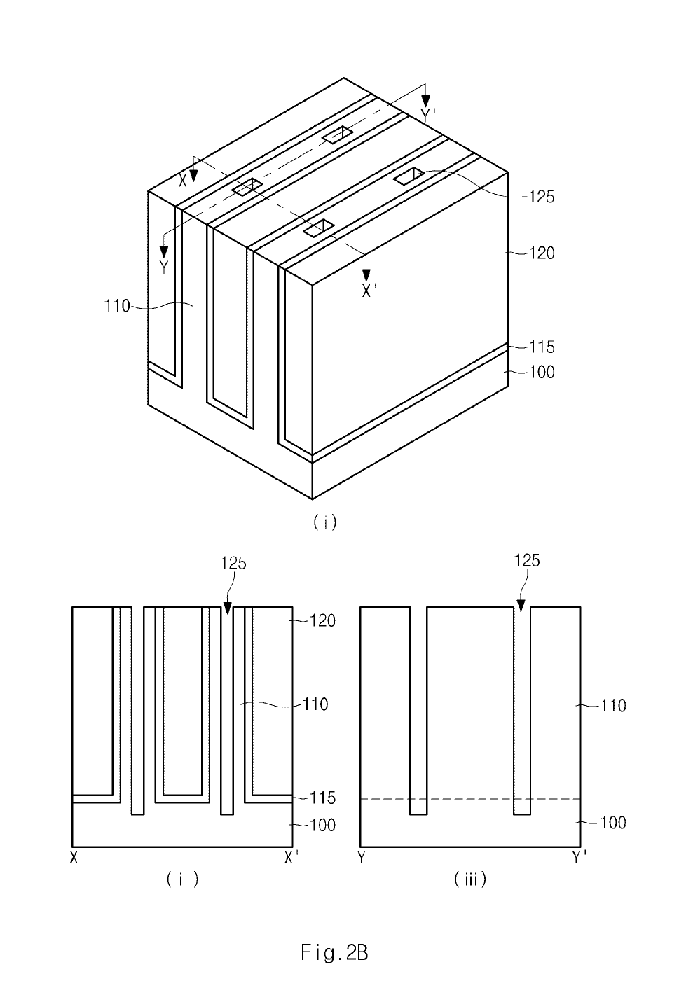

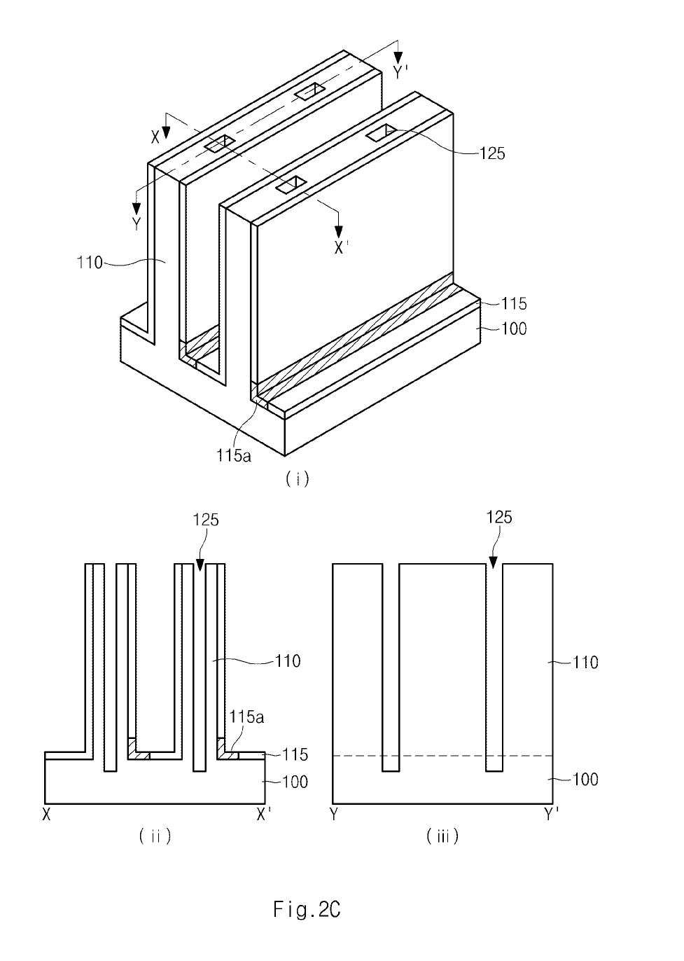

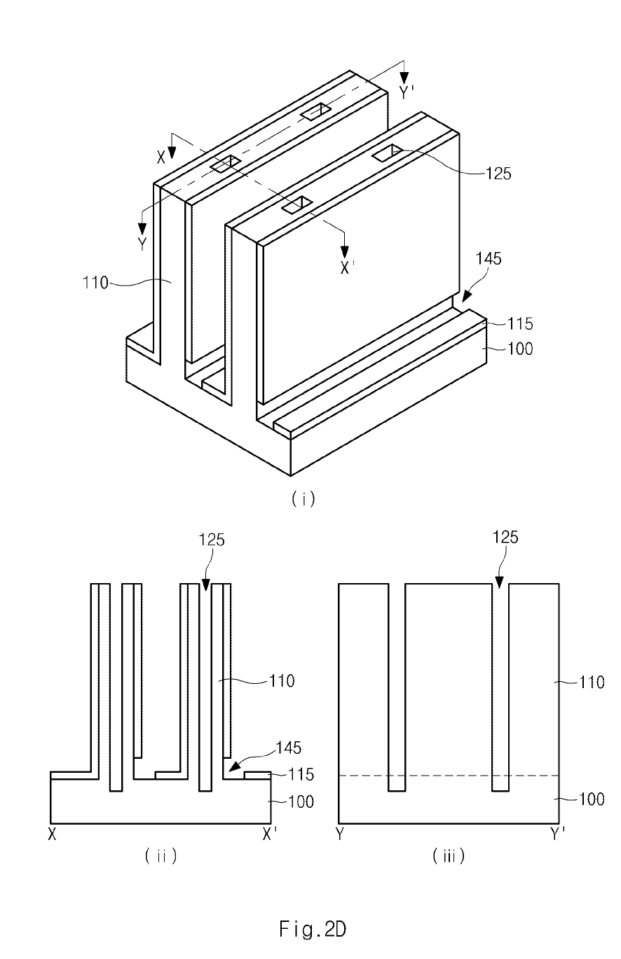

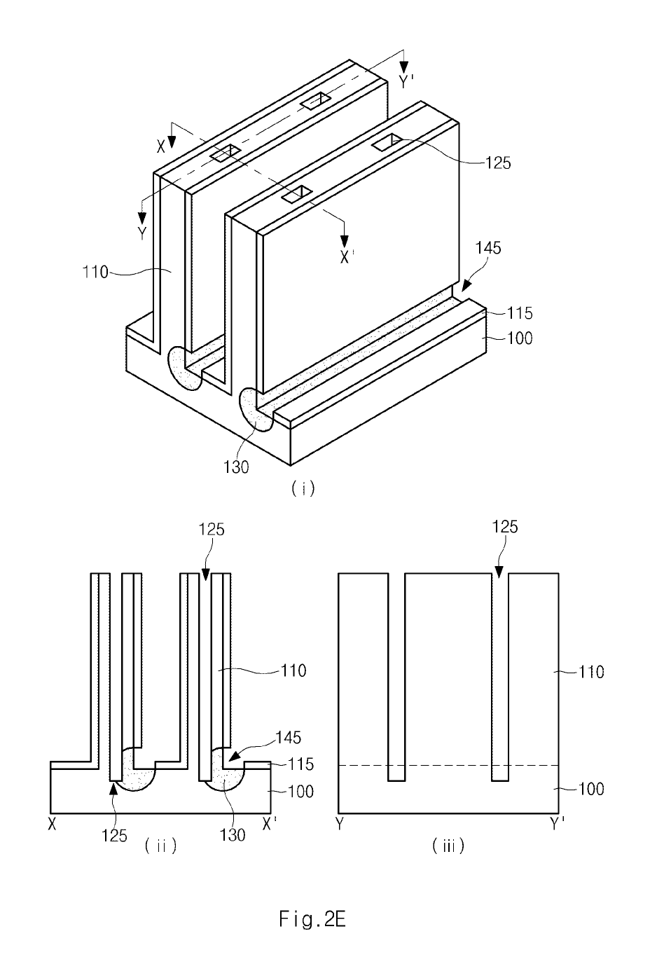

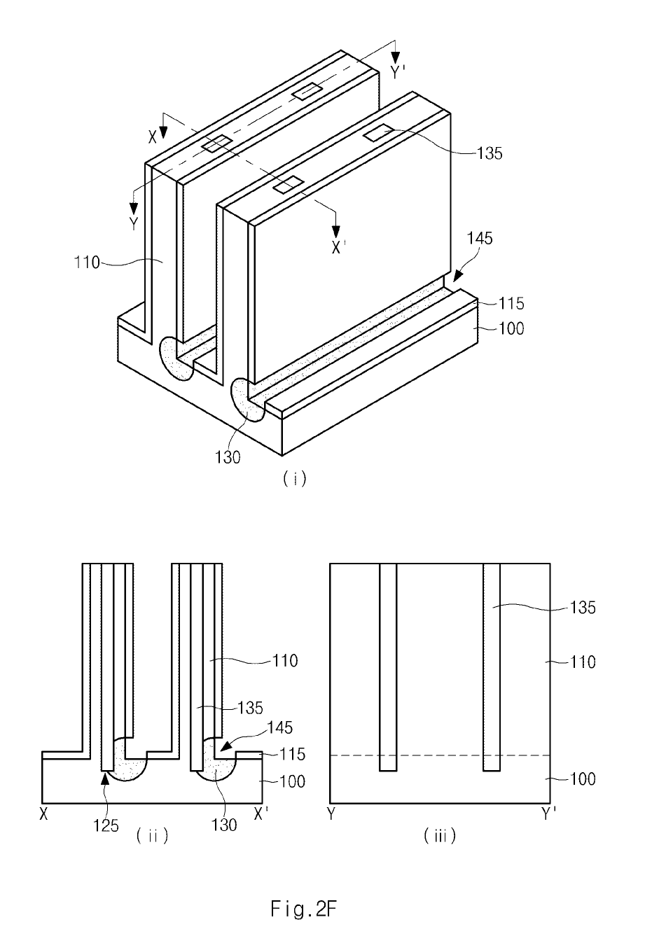

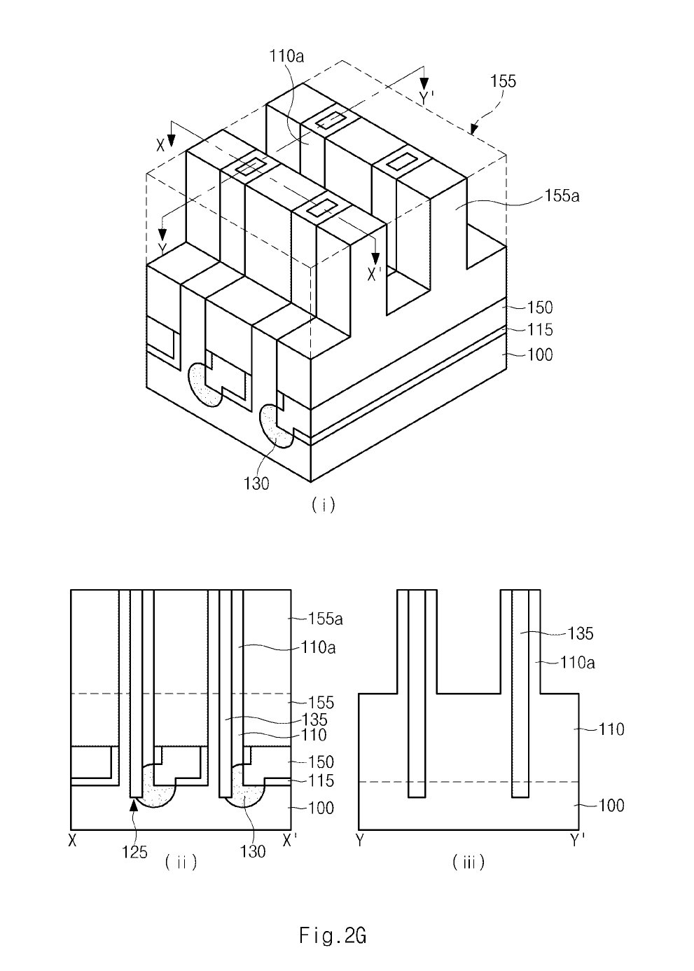

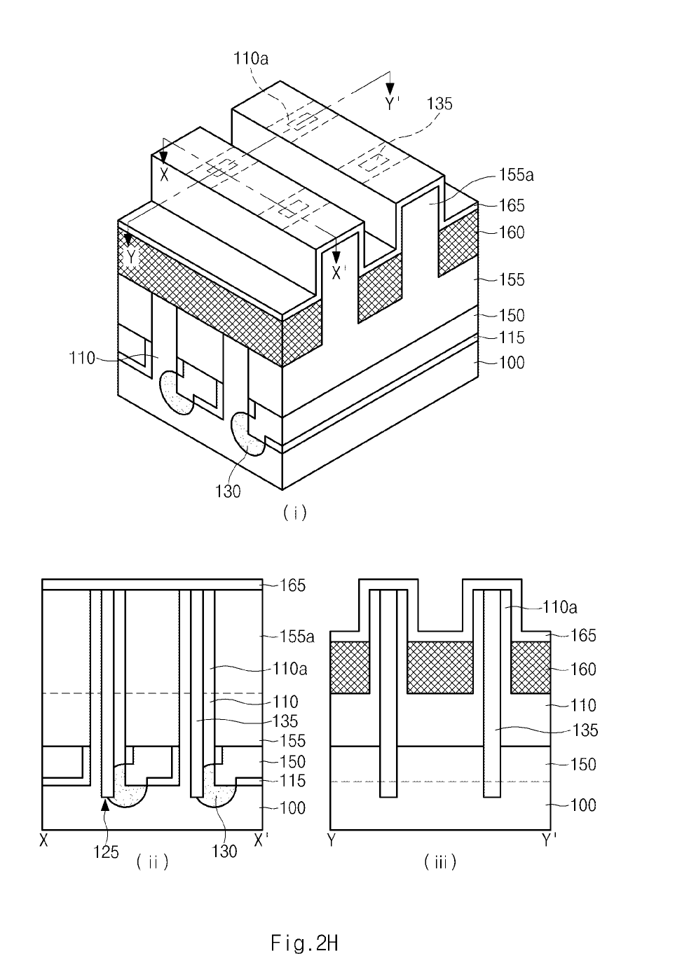

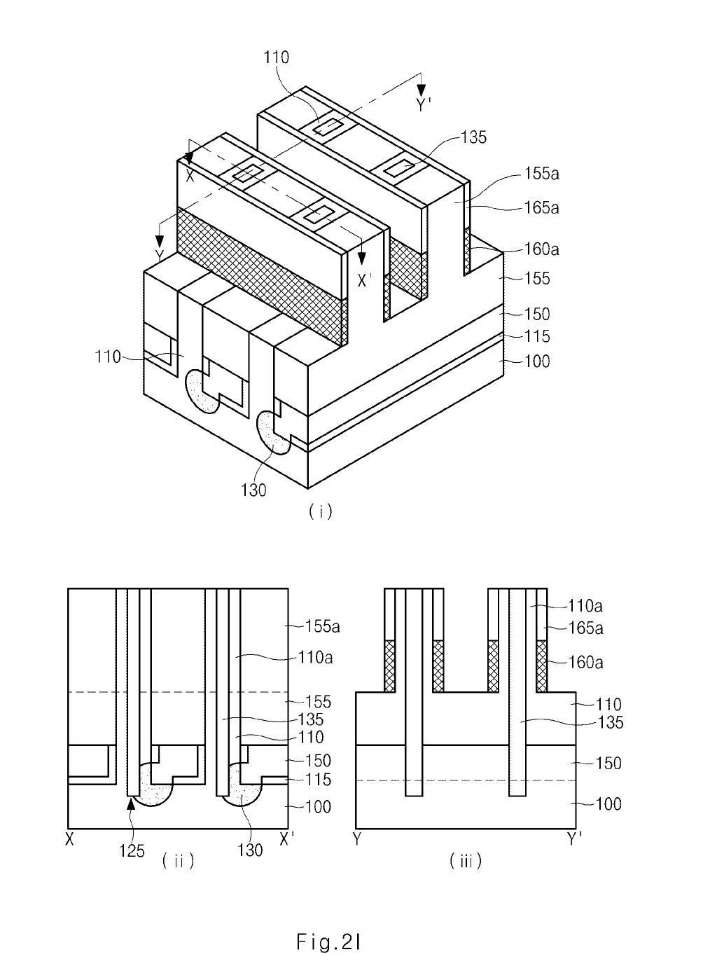

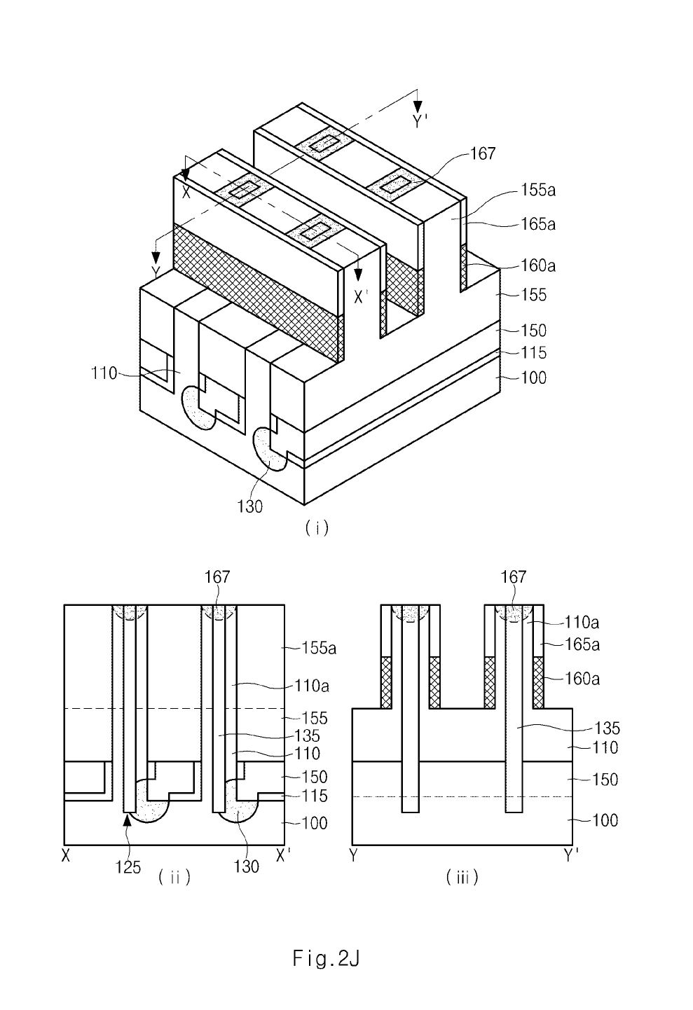

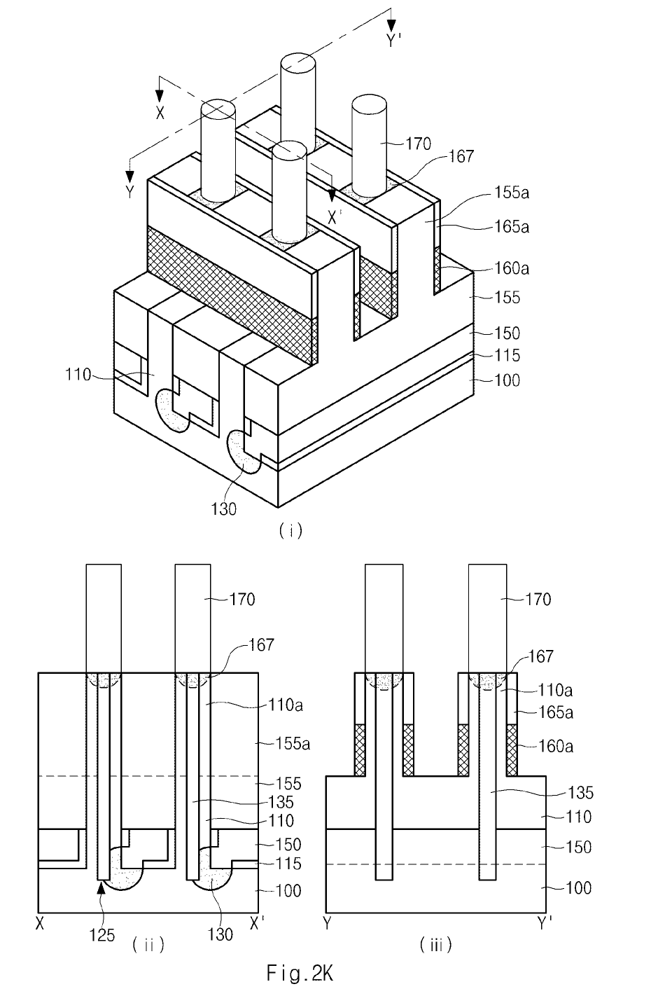

FIGS. 2A to 2K are perspective and cross-sectional views illustrating a method for manufacturing a semiconductor device according to an embodiment of the present invention. A method for manufacturing the semiconductor device including a vertical gate will hereinafter be described with reference to FIGS. 2A to 2K. FIGS. 2A(ii) to 2I(ii) are cross-sectional views of the semiconductor device taken along the line X-X′ of FIGS. 2A(i) to 2K(i), and FIGS. 2A(iii) to 2K(iii) are cross-sectional views of the semiconductor device taken along the line Y-Y′ of FIGS. 2A(i) to 2K(i).

Referring to FIG. 2A, a plurality of line patterns 110 may be formed by etching the semiconductor substrate 100. The line pattern 110 extends along the direction of the line Y-Y′ shown in FIG. 1. Thereafter, a liner polysilicon layer 115 is deposited over the semiconductor substrate 100 including the line pattern 110. In an embodiment, the liner polysilicon layer 115 may have a thickness of about 50 Å˜100 Å. An insulation film 120 is formed over the entire surface including the line pattern 110 and the liner polysilicon layer 115. The insulation film 120 may be formed of an oxide film.

Referring to FIG. 2B, the oxide film 120 and the liner polysilicon layer 115 formed over the line pattern 110 are planarized so that an upper part of the line pattern 110 is exposed. Thereafter, a hole-type mask pattern (not shown) is formed over the line pattern 110, the liner polysilicon layer 115, and the oxide film 120. Preferably, the mask pattern (not shown) may be formed in a manner that a hole is defined in the line pattern 110.

Subsequently, the line pattern 110 is etched using the mask pattern (not shown) as an etch mask, so that a plurality of holes 125 are formed in the line pattern 110. The plurality of holes 125 in the line pattern may be arranged along the same direction in which the line pattern 110 extends, and may be formed to a depth that is deeper than a bottom of the line pattern 110. That is, the holes 125 may extend into the substrate 100. For example, if the line pattern 110 is formed to have the height of 400 Å˜600 Å, the hole 125 may be etched to a depth of 600 Å˜800 Å.

Referring to FIG. 2C, after the oxide film 120 is removed, ions are implanted in a portion of the liner polysilicon layer 115 formed at the bottom part of one sidewall of the line pattern 110 so that a doped polysilicon layer 115a is formed. The ion implantation process may be performed two times. During a first ion implantation process, ions may be implanted into a portion of the liner polysilicon layer 115 formed over the surface of semiconductor substrate 100 and disposed between the line patterns 110. This ion implantation may be performed at a tilt angle of about 5°˜10° with respect to the surface of the semiconductor substrate 100. Thereafter, a second ion implantation process may be performed from a different direction from the first ion implantation process, and ions are implanted in the portion of the liner polysilicon layer 115 formed at the bottom of one sidewall of the line pattern 110. In an embodiment, the second ion implantation process may be performed at a larger angle than the first ion implantation process. For example, the second ion implantation process may be performed at a tilt angle of about 10°˜15° with respect to the surface of the semiconductor substrate 100. In addition, the second ion implantation process may be performed with an energy power at such a level that it does not affect the semiconductor substrate 100. For example, the second ion implantation process may be performed with energy of about 2˜5 KeV.

Referring to FIG. 2D, the doped polysilicon layer 115a is removed so that a sidewall contact 145, exposing the silicon layer of the line pattern 110, is formed.

Referring to FIG. 2E, ions are implanted into one side of the line pattern 110 through the sidewall contact 145, so that the bit line junction region 130 is formed at a bottom part of one side of the line pattern 110. Preferably, ion implantation for forming the bit line junction region 130 may be performed with an energy power of 20˜40 keV using any of arsenic (As), phosphorous (P), and a combination thereof. This ion implantation process may be performed using a tilted ion implantation process. Preferably, ion implantation is performed at a tilt angle of 5°˜15° with respect to the surface of the semiconductor substrate 100, for example.

In the process for forming the bit line junction region 130 through ion implantation, the hole 125 formed in the line pattern 110 causes the diffusion (or implantation) to stop when the bit line junction region 130 reaches the hole 125. Since a predetermined distance between the bit line junction region 130, formed at the bottom of one line pattern 110, and an adjacent line pattern 110 is maintained, the adjacent line pattern 110 in the region reserved for a pillar pattern 110a, which is formed in a subsequent process, is not isolated form the substrate 100. Thus the floating body effect can be prevented.

Referring to FIG. 2F, a silicon layer 135 is formed by filling the hole 125 in the line pattern 110 with the same material that the line pattern 110 is formed of. The process for forming the silicon layer 135 may be performed by growing a selective epitaxial growth (SEG) film that uses the silicon layer of the line pattern 110 exposed by the hole 125 as a seed. Preferably, the process for growing the SEG film may be performed until the SEG film contacts with the silicon layer 135 at an upper part of the hole 125. However, a variety of methods for burying the hole 125 may be used. For example, a method for depositing the silicon layer 135 in the hole 125, etc. may also be employed. In this case, when the silicon layer 135 fills the hole 125, since a critical dimension (CD) of the hole 125 is very small, the silicon layer 135 may not completely fill the hole 125, such that a void occurs. This void can prevent a storage node junction region, which will be formed in a subsequent process, from being formed to a predetermined depth.

Referring to FIG. 2G, a bit line conductive material 150 is formed over the semiconductor substrate 100 including the bit line junction region 130 exposed by the sidewall contact 145. The bit line conductive material 150 may be formed of any of a titanium (Ti) film, a titanium nitride (TiN) film, a tungsten (W) film, and a combination thereof. Preferably, the bit line conductive material 150 may be formed of a laminate structure of a TiN film and a Ti film, or a laminate structure of a TiN film and a tungsten (W) film. The bit line conductive material 150 is etched by an etch-back process, so that the resultant bit line conductive material 150 remains only at a bottom part between the line patterns 110. The resultant bit line conductive material is referred to as a buried bit line. Then, the liner polysilicon layer 115 formed over the line pattern 110 is removed. A second insulation film 155 is formed over the entire surface including the semiconductor substrate 100. The second insulation film 155 may include, for example, an oxide film. For example, the oxide film may be formed of at least one of a Spin-On-Dielectric (SOD) oxide film, a High Density Plasma (HDP) oxide film, etc. More preferably, a SOD oxide film and a HDP oxide film may be sequentially deposited.

A mask pattern (not shown) for defining a gate is formed over the second insulation film 155. The mask pattern (not shown) may be configured in the form of a line. Preferably, the mask pattern may extend in a direction (Y-Y′ direction of FIG. 1) perpendicular to the buried bit line. Upper parts of the second insulation film 155 and the line pattern 110 are etched using the mask pattern (not shown) as an etch mask, such that a pillar pattern 110a and an insulation film pattern 155a, opening a specific region to be used as a gate, are formed. Preferably, the etching process may be performed in a manner such that silicon layer 135 is disposed in the center of each pillar pattern 110a.

Referring to FIG. 2H, a gate conductive film 160 is formed over the semiconductor substrate 100 including the insulation film pattern 155a.

Thereafter, an etch-back process is performed so that the gate conductive film 160 remains only at the bottom part between the pillar patterns 110a. Subsequently, a spacer material 165 is deposited over the entire surface including the pillar pattern 110a and the gate conductive film 160. The spacer material 165 may be formed of any of an oxide film, a nitride film, and a combination thereof. Preferably, a nitride film and an oxide film may be sequentially formed. Referring to FIG. 2I, the spacer material 165 is subject an etch-back process to form a spacer 165a is formed at sidewalls of the insulation film pattern 155a and the pillar pattern 110a upon completion of the etch-back process. Thereafter, the gate conductive film is etched using the spacer 165a as a mask, so that a gate 160a is formed at a sidewall of the insulation film pattern 155a.

Referring to FIG. 2J, ions are implanted in an upper part of the pillar pattern 110a so that a storage node junction region 167 is formed. Alternatively, although not shown in FIG. 2J, a silicon layer of the exposed pillar pattern 110a may be grown so as to form a storage node contact (not shown). Then, an insulation film (not shown) may be further deposited over the storage node contact (not shown) and subject to a planarization process until the storage node contact (not shown) is exposed. Neighboring storage node contacts (not shown) are isolated from each other by the planarized insulation film.

Referring to FIG. 2K, a storage node 170 coupled to either the storage node junction region 167 or the storage node contact (not shown), depending on the embodiment, is formed over the pillar pattern 110a. The storage node 170 may have a cylinder shape, but is not limited thereto.

As is apparent from the above description, after the hole 125 is formed in the line pattern 110, an ion implantation process for forming the bit line junction region 130 is performed. Thus, a predetermined distance is guaranteed between the bit line junction region 130 and one side of the line pattern 110. As a result, a body tied structure is obtained and the floating body effect can be efficiently prevented.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a plurality of pillar patterns formed over a semiconductor substrate, and each pillar pattern includes a silicon pattern;
a bit line junction region formed at a bottom part of a first side of the pillar pattern, the bit line junction region being in contact with the silicon pattern;
a bit line provided between the pillar patterns, coupled to the bit line junction region, and extending along a first direction; and
a gate spaced apart from an upper part of the bit line, extending along a second direction perpendicular to the first direction, and formed at sidewalls of the pillar patterns.

2. The semiconductor device according to claim 1, wherein the pillar pattern is formed by etching the semiconductor substrate.

3. The semiconductor device according to claim 1, wherein each pillar pattern includes one silicon pattern.

4. The semiconductor device according to claim 1, wherein the silicon pattern extends deeper than the pillar pattern.

5. The semiconductor device according to claim 1, wherein the bit line is includes any of titanium (Ti) film, titanium nitride (TiN) film, tungsten (W) film, and a combination thereof.

6. The semiconductor device according to claim 1, wherein the gate is coupled to the plurality of pillar patterns.

7. The semiconductor device according to claim 1, the device further comprising a storage node junction region formed over the pillar pattern.

8. The semiconductor device according to claim 6, the device further comprising a storage node coupled to the storage node junction region, which is provided at an upper part of the pillar pattern.

9. A method for manufacturing a semiconductor device comprising:
forming a plurality of line patterns over a semiconductor substrate;
forming a plurality of holes in the line pattern;
forming a bit line junction region at a bottom part of a first sidewall of the line pattern;
filling the hole to form a silicon layer;
forming a bit line between two neighboring line patterns;
forming an insulation film over the bit line;
forming a plurality of pillar patterns by etching the line pattern and the insulation film; and
forming a gate at a sidewall of the pillar patterns so that the gate extends in a direction that is perpendicular to a direction of the bit line.

10. The method according to claim 9, wherein the step of filling the hole to form the silicon layer includes:
forming a selective epitaxial growth (SEG) film by growing a silicon layer of the line pattern exposed by the hole.

11. The method according to claim 9, wherein the step of filling the hole to form the silicon layer includes:
depositing a silicon layer over the entire surface of the line pattern including the hole; and
performing a planarization etching process until an upper part of the line pattern is exposed.

12. The method according to claim 9, wherein the formation of the bit line junction region further includes:
implanting ions into the first sidewall of the line pattern.

13. The method according to claim 12, wherein the implantation of ions includes a primary ion implantation process and a secondary ion implantation process, each of which is performed by a tilted ion implantation process, wherein the primary ion implantation process is performed from a different direction to the secondary ion implantation process.

14. The method according to claim 13, wherein the primary ion implantation process is performed at an angle of 5°˜10° with respect to a surface of the semiconductor substrate.

15. The method according to claim 13, wherein the secondary ion implantation process is performed at an angle of 10°˜15° with respect to a surface of the semiconductor substrate.

16. The method according to claim 10, wherein the formation of the selective epitaxial growth (SEG) film is performed until the silicon layer fills up to an upper part of the hole.

17. The method according to claim 9, wherein the bit line is formed of any one of a titanium (Ti) film, a titanium nitride (TiN) film, a tungsten (W) film, and a combination thereof.

18. The method according to claim 9, wherein, in the formation of the pillar pattern, each of the pillar patterns is formed to have one hole.

19. The method according to claim 9, wherein the formation of the gate further includes:
forming a gate conductive material at a bottom part between the pillar patterns;
forming a spacer over the gate conductive material and at a sidewall of each pillar pattern; and
etching the gate conductive material using the spacer as an etch mask.

20. The method according to claim 9, the method further comprising:
after the formation of the gate,
forming a storage node junction region over the pillar patterns; and
forming a storage node coupled to the storage node junction region over the pillar patterns.

21. A semiconductor device comprising:
an inner pillar extending upward from a substrate;
an outer pillar surrounding the inner pillar;
a bit line junction region formed in a first sidewall region of the outer pillar.

22. The semiconductor device of claim 21,
wherein the outer pillar includes a second sidewall region coupled to the substrate, and
wherein the second sidewall region is spaced apart from the first sidewall region by the inner pillar.

23. The semiconductor device of claim 21,
wherein the outer pillar includes the substrate material.

24. The semiconductor device of claim 21,
wherein the inner pillar includes a same material as the outer pillar or as the substrate material.

25. The semiconductor device of claim 21,
wherein the inner pillar extends down to a first level,
wherein the bit line junction region is formed at a second level, and
wherein the first level is lower than the second level.

26. The semiconductor device of claim 21,
wherein the inner pillar extends down to a first level,
wherein the outer pillar extends down to a third level, and
wherein the first level is lower than the third level.

27. The semiconductor device of claim 22,
wherein the bit line junction region extends to an interface of the inner and the outer pillars, and
wherein the bit line junction region does not extend to the second sidewall region of the outer pillar.

28. The semiconductor device of claim 21,
wherein the inner and the outer pillars are configured in a concentric pattern.

29. A method for manufacturing a semiconductor device comprising:
forming a line pattern extending upward from a substrate and arranged along a first direction;
patterning the line pattern to form an outer pillar having a hole inside;
filling the hole to form an inner pillar pattern extending down to a first level; and
forming a bit line junction region in a first sidewall region of the outer pillar.

30. The method of claim 29, wherein the step of patterning the line pattern to form the outer pillar comprises:
forming the hole inside the line pattern to extend down to the first level; and
patterning the line pattern along a second direction perpendicular to the first direction to form the outer pillar pattern having the hole inside.

31. The semiconductor device of claim 29,
wherein the inner and the outer pillars are configured in a concentric pattern.
